(19) United States
(12) Patent Application Publication
(10) Pub. No.: US 2025/0218930 A1
(43) Pub. Date: Jul. 3, 2025

(54) CROSS-COUPLE CONSTRUCT WITH SHIFTED GATE CONTACT

(71) Applicant: INTERNATIONAL BUSINESS MACHINES CORPORATION, Armonk, NY (US)

(72) Inventors: Albert M. Chu, Nashua, NH (US); Ravikumar Ramachandran, Pleasantville, NY (US); Brent A. Anderson, Jericho, VT (US); Charles Nicholas Perez, Burlington, VT (US); Jason J Stuffle, Burlington, VT (US)

(21) Appl. No.: 18/398,848

(22) Filed: Dec. 28, 2023

(51) Int. Cl. H01L 23/522; H01L 27/085

(52) U.S. Cl. CPC H01L 23/5226; H10D 84/82

(57) ABSTRACT

A semiconductor device includes a first diffusion region having a longitudinal axis and a second diffusion region parallel with the first diffusion region. A source/drain contact contacts the first diffusion region and the second diffusion region. A gate has a centerline in a transverse direction to the longitudinal axis. A gate contact connects to the gate at a position that has an offset from the centerline away from the source/drain contact.

### BACKGROUND

The present invention generally relates to semiconductor devices and processing methods, and more particularly to modified gate contacts which are offset to adjust contact pitch and to add distance from source/drain contacts to minimize risk of shorts.

Transistor gate pitch referred to as contacted poly pitch (CPP) shrinks with each new generation of semiconductor device. As CPP shrinks, space between gate contacts and source/drain contacts also shrinks. As these components have less space between them, short circuit failures can begin to increase. This issue is compounded by the fact that performance of these devices needs to exceed performance of previous generations of devices.

Options for the placement of components, such as gate contacts, are limited especially among source/drain contacts which compete for available space. This makes gate and gate contact placement exceedingly difficult in view of decreasing sizes of source/drain regions.

Therefore, a need exists for alternate gate connection methods and wiring that preserves the electrical integrity of conductive components but provides efficient wire routing within the constraints of ever decreasing node sizes.

### SUMMARY

In accordance with an embodiment of the present invention, a semiconductor device includes a first diffusion region having a longitudinal axis and a second diffusion region parallel with the first diffusion region. A source/drain contact contacts the first diffusion region and the second diffusion region. A gate has a centerline in a transverse direction to the longitudinal axis. A gate contact connects to the gate at a position that has an offset from the centerline away from the source/drain contact.

In some embodiments, the gate can be positioned closer to the source/drain contact than to the gate contact. The gate contact can extend over a source/drain region. The gate contact can extend further in the transverse direction than along the longitudinal axis. The gate contact can have a portion that overhangs the gate. The portion that overhangs the gate can extend over a gate sidewall spacer. The gate contact can include a plurality of gate contacts on opposite sides of the source/drain contact and the plurality of gate contacts can be shifted off-center in opposite directions from the source/drain contact. The offset can be up to 50% of a width of the gate contact.

In accordance with an embodiment of the present invention, a semiconductor device includes a P-type source/drain region, an N-type source/drain region disposed in a parallel direction and spaced apart from the P-type source/drain region and a source/drain contact contacting the P-type source/drain region and the N-type source/drain region. First gates span over the P-type source/drain region and the N-type source/drain region on a first side of the source/drain contact. The first gates have a centerline in a transverse direction to the parallel direction. Second gates span over the P-type source/drain region and the N-type source/drain region on a second side of the source/drain contact opposite the first side. The second gates have a centerline in a transverse direction to the parallel direction. First gate contacts connect to the first gates at a position that is offset from the centerline of the first gates away from the source/drain contact, and second gate contacts connect to the second gates at a position that is offset from the centerline of the second gates away from the source/drain contact.

In some embodiments, the first gate contacts can be positioned off-center relative to the P-type source/drain region and the N-type source/drain region. The second gate contacts can be positioned off-center relative to the P-type source/drain region and the N-type source/drain region. The first gate contacts can be longer in the transverse direction. The second gate contacts can be longer in the transverse direction. At least one gate contact of the first gate contacts and the second gate contacts can have a portion that overhangs a gate corresponding to the at least one gate contact. The portion that overhangs the gate can overlap a gate sidewall spacer. The first gate contacts and the second gate contacts can be shifted off-center in opposite directions from the source/drain contact. At least one gate contact of the first gate contacts and the second gate contacts can include an offset is up to 50% of a width of the at least one gate contact in the parallel direction.

In accordance with an embodiment of the present invention, a semiconductor device includes a source/drain contact contacting parallel source/drain regions, a gate having a centerline in a transverse direction to the parallel source/drain regions and a gate contact connecting to the gate at a position that is offset from the centerline away from the source/drain contact.

In other embodiments, the gate contact can be longer in the transverse direction. The gate contact can have a portion that overhangs the gate.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 shows a top down layout view of active regions, gates and contacts for a semiconductor substrate with gate contacts shifted off a centerline pitch of the gates away from a source/drain contact, in accordance with an embodiment of the present invention;

FIG. 2 shows the layout view and three cross-sectional views taken at section lines T, S and U showing gate contacts shifted away from the source/drain contact of the semiconductor device, in accordance with an embodiment of the present invention;

FIG. 3 shows the layout view and a schematic diagram of a cross-coupled circuit representing the layout view of the semiconductor device, in accordance with an embodiment of the present invention; and

FIG. 4 shows a top-down layout view with gate contact extended along gate edges for a semiconductor substrate, in accordance with an embodiment of the present invention.

### DETAILED DESCRIPTION

In accordance with embodiments of the present invention, devices and methods are described which include gate contacts that are reconfigured to employ limited available space within a gate contact layer. In useful embodiments, a gate contact is shifted away from source/drain contacts without interfering with contacts or other metal structures. Instead of being centered on a centerline of a gate conductor (fully strapped on a gate) the gate contact is arranged to favor one side or two sides of the gate line to permit a greater amount of space between the source/drain contact and the gate contact. This can include a partially strapped gate connection. In one embodiment, the gate contact can overlap a dielectric sidewall spacer for the gate. By optimizing placement of the gate contact or contacts, shorting risks can be greatly reduced.

Gate contact reconfiguration (e.g., offset from a gate metal centerline away from adjacent source/drain contacts) can improve cross-couple constructs. A conventional cross-couple construct requires three contacted poly pitches (CPP). In accordance with the present embodiments, with the shifting of gate contacts, a two CPP construct is made possible by enabling Contact Over Active Gate (COAG). COAG is an enhanced semiconductor process that removes the need for the gate contact to land at an end-to-end (ETE) spacing region and instead permits the gate contact to be placed over an active gate region to reduce dead space between transistor devices. COAG can include a direct placement of the gate contact. However, COAG calls for tight spacing between the gate contact and the source/drain contact. This tight spacing causes manufacturing difficulty as well as limits the CPP reduction. Gate contact offset, in accordance with the present embodiments, enables a two contacted poly pitch (CPP) cross-couple while minimizing short risk of the gate contacts to source/drain (S/D) contacts.

In one embodiment, the gate contact is elongated with a rectangular shape having a long edge parallel to a gate edge. The gate contact can be in partial contact with the gate (e.g., does not fully strap across gate). If the gate contact extends beyond the gate (partially strapped), the gate contact can extend onto or over the dielectric sidewall spacer. In one embodiment, the gate contact can be increased in size by elongating its dimension in a direction parallel with the gate line. The elongated gate contact provides increased gate contact area without increasing risks due to shorting. The elongated gate contact can also ensure that contact resistance is controlled.

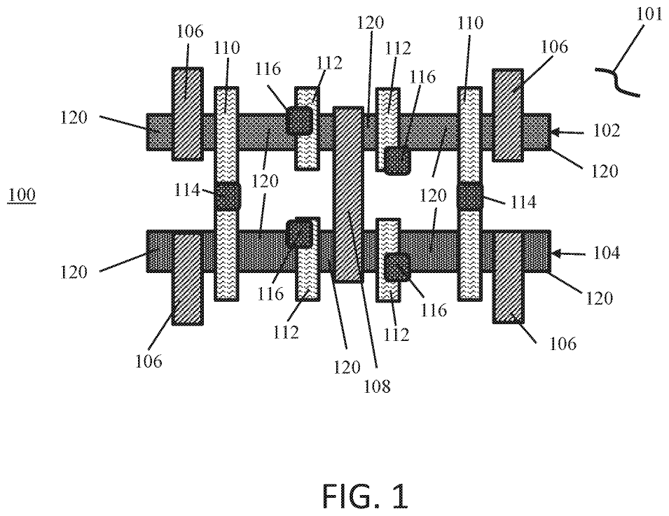

Referring now to the drawings in which like numerals represent the same or similar elements and initially to FIG. 1, a device layout 100 is shown in accordance with embodiments of the present invention. Device layout 100 depicts an illustrative layout having gate contacts 116 shifted away from a source/drain contact 108. Instead of being centered on a centerline of a gate 112 (fully strapped), the gate contact 116 is arranged to favor one side or two sides of the gate 112 to permit a greater amount of space between the source/drain contact 108 and the gate contact 116. In one embodiment, the gate 112 can be positioned closer to the source/drain contact 108 than the gate contact 116.

Device layout 100 includes a substrate 101 on which diffusion regions or active regions 102 and 104 are formed. For viewing purposes, the device layout 100 omits dielectric layers surrounding the active regions 102, 104, gates 110, 112, source/drain (S/D) contacts 106, 108, gates 110, 112 and gate contacts 114, 116. Active regions 102, 104 extend along a longitudinal axis and are disposed in a parallel relationship with one another. Active regions 102, 104 include S/D regions for transistor devices, and gates 110, 112 are transversely disposed relative to the active regions 102, 104 for field effect transistor devices. Transistor channels are formed on the active regions 102, 104 below the gates 110, 112. In the illustrative embodiment shown, active region 102 is employed with P-type field effect transistors (PFETs) and active region 104 is employed with N-type field effect transistors (NFETs). This can be reversed with active region 102 being employed with NFETs and active region 104 being employed with PFETs.

The substrate 101 can include any suitable substrate structure, e.g., a bulk semiconductor, a semiconductor-on-insulator (SOI) substrate, etc., and preferably includes a monocrystalline semiconductor. In one example, the substrate 101 can include a silicon-containing material. Illustrative examples of Si-containing materials suitable for the substrate 101 can include, but are not limited to SiGe, SiGeC, SiC and multi-layers thereof. Although silicon is the predominantly used semiconductor material in wafer fabrication, alternative semiconductor materials can be employed as additional layers, such as, but not limited to, germanium, gallium arsenide, gallium nitride, silicon germanium, cadmium telluride, zinc selenide, etc.

The active regions 102, 104 can be formed on or in the substrate 101. In one embodiment, the S/D regions of the active regions 102, 104 are epitaxially grown on the substrate 101. The epitaxially grown active regions 102, 104 can include epitaxially grown Si, SiGe or other suitable monocrystalline materials. The epitaxially grown active regions 102, 104 can be doped during formation with N-type or P-type dopants, as appropriate.

S/D regions 120 can include, e.g., doped Si or SiGe and include faceted surfaces when epitaxial growth is not confined. In one embodiment, the S/D regions 120 can be designated as P-type or N-type devices, respectively. The P-type and N-type devices can have different materials selected for the S/D regions 120. For example, if the source/drain region is a PFET, boron doped SiGe can be employed. For example, if the source/drain region is an NFETs, phosphorous doped Si can be employed. The source/drain regions 120 can be appropriately doped during their formation, e.g., during epitaxial growth. It should be understood that other dopants and materials can be employed for the S/D regions 120.

S/D regions 120 occupy regions in between gates 110, 112. Gates 110, 112 separate S/D regions 120 such that when activated the gates 110, 112 permit conduction of charge through a channel occupying a region between adjacent S/D regions 120 under the gates 110, 112. S/D regions 120 are connected to power or signal lines through S/D contacts 106, 108. Gates 110, 112 are connected to power or signal lines through gate contacts 114, 116.

In an embodiment, S/D contact 108 extends across and connects the active regions 102, 104. S/D contact 108 is disposed in a transverse direction to the longitudinal axis of the active regions 102, 104. In an embodiment, S/D contact 108 can include an output for a cross-coupled device. Cross-coupled devices include transistors having their gates connected to each other's drains. The proximity of the S/D contact 108 to nearby gate contacts 116 can cause crosstalk and leakage problems; however, of greater concern is the potential for shorts. In accordance with an embodiment, the gate contacts 116 are shifted or offset from a centerline of the gate 112 to increase the distance between the S/D contact 108 and the gate contacts 116.

The gate contacts 116 can be shifted away from the S/D contact 108 parallel to a longitudinal axis of the active regions 120 or transversely to the longitudinal axis of the active region 120 or both. The repositioning of the gate contacts 116 can be optimized to include a furthest distance, reduced crosstalk, better usage of the available space, ease of manufacturing, etc. It should be noted that the gate contacts 116 can be fabricated to only partially land (partially strap) on the corresponding gate 112. This can include a portion of the gate contact 116 overhanging gate 112, to which the gate contact 116 is connected. In some embodiments, the gate contact 116 can be offset in the longitudinal direction of the active regions 102 or 104. In this instance, the gate contact 116 can also hang over or extend over the gate sidewall spacer of the gate 112 and possibly over a S/D region 120 in its entirety or partially.

In addition, the gate contacts 116 can be positioned off-center relative to the active regions 102, 104 and therefore the S/D regions 120. For example, the gate contacts 116 can be positioned off-center from a longitudinal axis or centerline of the active regions 102, 104 and (S/D regions 120).

The gates 110, 112, gate contacts 114, 116 and S/D contacts 106, 108 are formed with one or more dielectric layers (not shown), such as, e.g., an interlevel dielectric layer (ILD). The dielectric layer(s) can include any suitable material, e.g., silicon containing materials such as SiO₂, Si₃N₄, SiOₓN_{y}, SiC, SiCO, SiCOH, and SiCH compounds, etc. The dielectric layer 122 can be deposited using any suitable deposition methods.

Openings for the formation of conductive structures, such as gates 110, 112, gate contacts 114, 116 and S/D contacts 106, 108 can include a diffusion barrier prior to a conductive fill. For example, a diffusion barrier can be formed in trenches prior to a conductive fill. The diffusion barrier can include, e.g., TiN, TaN, or similar materials. For S/D contacts 106, 108, a silicide liner, such as Ti, Ni, NiPt can be deposited before a diffusion barrier in the trenches prior to the conductive fill.

A conductive fill for forming gate contacts 116 can include materials, such as, e.g., Cu, Ru, Mo, Rh, W, Ir, and alloys or combinations of these and other conductive materials. In a particularly useful embodiment, the conductive fill includes Cu. The conductive fill can be formed using a deposition method, such as, e.g., chemical vapor deposition (CVD), plasma enhanced CVD (PECVD), atomic layer deposition (ALD) or any other suitable deposition method.

It should be understood that the device layout 100 illustratively depicts a useful circuit configuration, e.g., a cross-couple construct. Other circuit configurations can also benefit from the teachings in accordance with embodiments of the present invention.

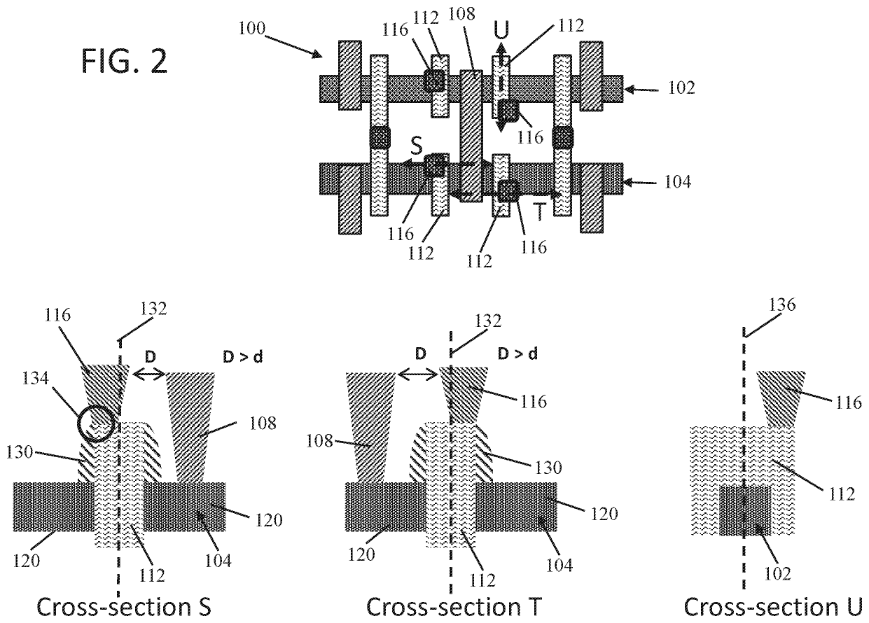

Referring to FIG. 2, cross-sectional views of the device layout 100 are shown. One cross-sectional view is taken at section line S and shows gate contact 116 shifted away from S/D contact 108. In a conventional design, the distance between the gate contact 116 and the S/D contact 108 can be represented by d. In accordance with the present embodiments, the distance between the gate contact 116 and the S/D contact 108 is represented by D which is greater than d. The gate contact 116 is shifted from a centerline 132 of the gate 112.

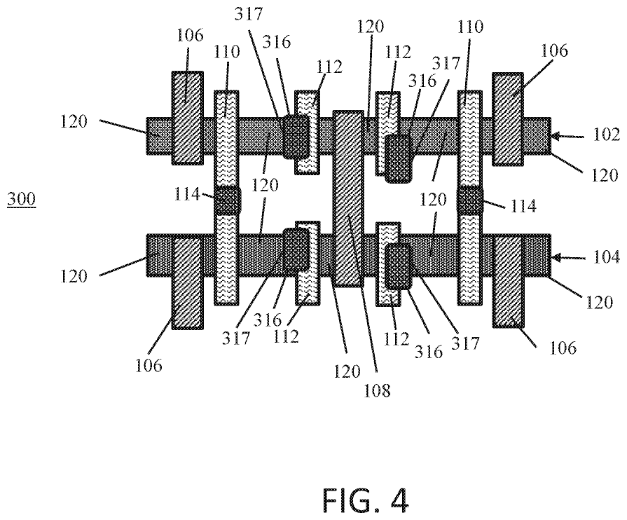

In this embodiment, the gate contact 116 retains its size and is shifted away from the contact 108 even if the gate contact 116 only partially lands on the gate 112. As indicated in cross-section S, gate contact 116 is shifted to have a small overlap onto a top of a gate sidewall spacer 130, shown in region 134. In one embodiment, at least 50% of a footprint of gate contact 116 lands on the gate 112. This percentage can change in accordance with performance criteria that are needed for proper operation. Adjustments in a length of contact between the gate contact 116 and the gate 112 can also be adjusted as will be described with reference to FIG. 4. The gate contact 116 can be extended longitudinally along the gate 112 to ensure adequate contact with the gate 112 while controlling contact resistance, spacing relative to the S/D contact 108 and addressing capacitance issues. In some embodiments, the gate contact 116 can partially hang over an underlying active S/D region 120 and take advantage of available space while ensuring sufficient distance from the S/D contact 108.

Another cross-sectional view is taken at section line T and also shows gate contact 116 shifted away from S/D contact 108. In accordance with the present embodiments, the distance between the gate contact 116 and the S/D contact 108 can be represented as D which is greater than d. In cross-section T, the distance D is even greater than in cross-section S. The gate contact 116 is shifted from the centerline 132 of the gate 112.

In this embodiment, the gate contact 116 retains its size and is shifted away from the contact 108 even if the gate contact 116 only partially lands on the gate 112. As indicated in cross-section T, gate contact 116 is shifted to have a small overlap onto a top of a gate sidewall spacer 130. In one embodiment, the gate contact 116 can be extended longitudinally along the gate 112 to ensure adequate contact with the gate 112 while controlling contact resistance, spacing with the S/D contact 108 and addressing capacitance issues. In some embodiments, the gate contact 116 can partially hang over an underlying active S/D region 120 and take advantage of available space while ensuring sufficient distance from the S/D contact 108.

Another cross-sectional view is taken at section line U and shows gate contact 116 shifted in a direction parallel with a longitudinal axis of the S/D contact 108. In accordance with the present embodiments, the gate contact 116 can be shifted in a second direction to provide additional flexibility for the placement of gate contacts 116. Adjacent gate contacts 116 can be shifted in a same direction or in a different direction as needed. In one embodiment, all gate contacts adjacent to the S/D contact 108 can be shifted away radially in different directions to take advantage of available space. Shifting all the gates contacts 116 in a same column (or row) can yield enough space to permit a reduction in device pitch (e.g., CPP).

The gate contact 116 is shifted from a centerline 136 of the gate 112. In this embodiment, the gate contact 116 retains its size and is shifted away from the contact 108 even if the gate contact 116 only partially lands on the gate 112. In one embodiment, the gate contact 116 can be extended longitudinally along the gate 11, e.g., toward the centerline 136) to ensure adequate contact with the gate 112 while controlling contact resistance, spacing with the S/D contact 108 and addressing capacitance issues.

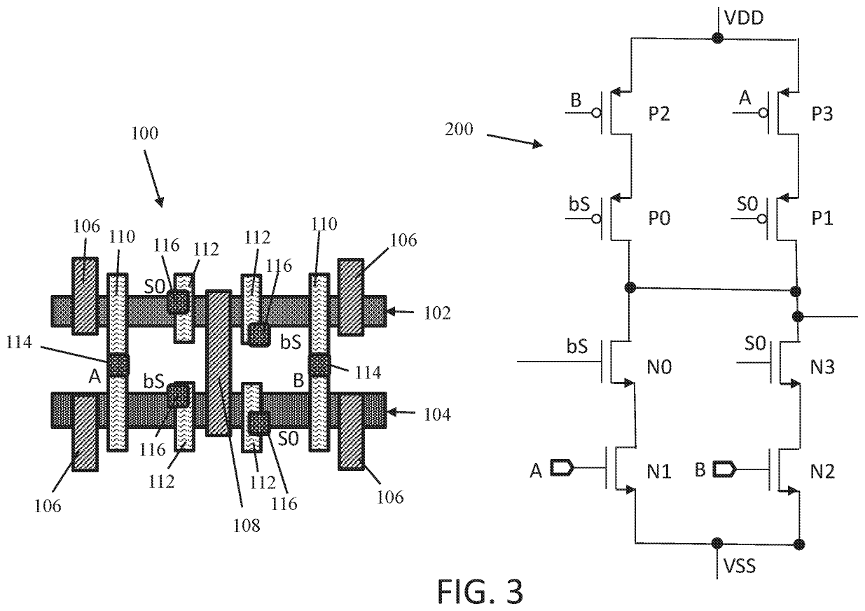

Referring to FIG. 3, a schematic diagram shows a cross-coupled transistor circuit 200 that can be realized from the device layout 100. Circuit 200 includes PFETs P0, P1, P2 and P3 and NFETs N0, N1, N2 and N3. PFETs P0, P1, P2 and P3 are associated with active region 102 while NFETs N0, N1, N2 and N3 are associated with active region 104. Gate contacts 114 and 116 are correspondingly labeled in the circuit 200 and in the device layout 100. The gate contacts 114, 116 are labeled A, B, bS and S0. VDD is positive supply voltage and VSS is negative supply voltage (e.g., ground).

In one embodiment, the shifting of the gate contacts 116 enables a two contacted poly pitch (CPP) circuit (circuit 200) to be realized instead of a conventional three CPP circuit. By reducing the gate contact pitch (CPP) a smaller layout is provided for circuit 200. Shifting all the gates contacts 116 in a same column (or row) can yield enough space to permit the reduction in device pitch (e.g., CPP).

Referring to FIG. 4, a device layout 300 is shown in accordance with another embodiment of the present invention. Device layout 300 depicts an illustrative layout having gate contacts 316 shifted away from the source/drain contact 108. Instead of being centered on a centerline of the gate 112, the gate contact 316 is arranged to favor one side or two sides of the gate 112 to permit a greater amount of space between the source/drain contact 108 and the gate contact 316. In one embodiment, the gate 112 can be positioned closer to the source/drain contact 108 than the gate contact 316.

Device layout 300 includes active regions 102 and 104. For viewing purposes, the device layout 300 also omits dielectric layers surrounding, the active regions 102, 104, gates 110, 112, source/drain (S/D) contacts 106, 108, gates 110, 112 and gate contacts 114, 316. Active regions 102, 104 represent S/D regions for transistor devices. In the illustrative embodiment shown, active region 102 is employed with PFETs and active region 104 is employed with NFETs. This can be reversed with active region 102 being employed with NFETs and active region 104 being employed with PFETs.

In an embodiment, S/D contact 108 can include an output for a cross-coupled device. The gate contact 316 is shifted from the centerline of the gate 112. In this embodiment, the gate contact 316 is extended longitudinally along the direction of the gate 112 (also along a direction parallel to a longitudinal axis of the S/D contact 108 and/or transverse to a longitudinal axis of the active regions 102, 104). A portion of the gate contact 316 overhangs the gate 112, to which the gate contact 316 is connected. In some embodiments, the gate contact 316 can be offset in the longitudinal direction of the active regions 102 or 104. In this instance, the gate contact 316 can also hang over or extend over the gate sidewall spacer of the gate 112 and possibly over a S/D region 120 in its entirety or partially.

In addition, the gate contacts 316 can be positioned off-center relative to the active regions 102, 104 and therefore the S/D regions 120. For example, the gate contacts 316 can be positioned off-center from a longitudinal axis or centerline of the active regions 102, 104 and (S/D regions 120).

An extended length of a side 317 of the gate contact 316 ensures adequate contact with the gate 112 while controlling contact resistance, spacing with the S/D contact 108 and addressing capacitance issues even if the gate contact 316 is fabricated to only partially land on the corresponding gate 112.

In an embodiment, the contact area between the gate 112 and the gate contact 316 is increased without reducing spacing between the gate contact 316 and the S/D contact 108. The gate contact 116 can only partially land on the gate 112 and still provide sufficient contact area. In some embodiments, one or more gate contacts adjacent to the source/drain contact 108 can be elongated or oversized while others may not be elongated or oversized.

In accordance with embodiments of the present invention, gate contacts 116 and 316 are repositioned during fabrication in accordance with a design of a particular semiconductor device. Gate contacts 116, 316 are sized and positioned in accordance with the design. The length of a side 317 of the gate contact can be determined and adjusted to provide sufficient contact with the gate 112. In some embodiments, the length of the gate contact 316 can be uniformly applied across like gate contacts. In other embodiments, the gate contacts 316 can include customized lengths and each can include a specific length, as needed.

Exemplary applications/uses to which the present invention can be applied include but are not limited to semiconductor devices. Semiconductor devices can include processors, memory devices, application specific integrated circuits (ASICs), logic circuits or devices, combinations of these and any other circuit device. In such devices, one or more semiconductor devices can be included in a central processing unit, a graphics processing unit, and/or a separate processor- or computing element-based controller (e.g., logic gates, etc.). The semiconductor devices can include one or more on-board memories (e.g., caches, dedicated memory arrays, read only memory, etc.). In some embodiments, the semiconductor devices can include one or more memories that can be on or off board or that can be dedicated for use by a hardware processor subsystem (e.g., ROM, RAM, basic input/output system (BIOS), etc.).

In some embodiments, the semiconductor devices can include and execute one or more software elements. The one or more software elements can include an operating system and/or one or more applications and/or specific code to achieve a specified result. In still other embodiments, the semiconductor devices can include dedicated, specialized circuitry that perform one or more electronic processing functions to achieve a specified result. Such circuitry can include one or more field programmable gate arrays (FPGAs), and/or programmable applications programmable logic arrays (PLAs).

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher-level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SixGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” “top,” “bottom” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of devices and methods (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A semiconductor device, comprising:
a first diffusion region having a longitudinal axis;
a second diffusion region parallel with the first diffusion region;
a source/drain contact contacting the first diffusion region and the second diffusion region;
a gate having a centerline in a transverse direction to the longitudinal axis; and
a gate contact connecting to the gate at a position that has an offset from the centerline away from the source/drain contact.

2. The semiconductor device as recited in claim 1, wherein the gate is positioned closer to the source/drain contact than the gate contact.

3. The semiconductor device as recited in claim 1, wherein the gate contact extends over a source/drain region.

4. The semiconductor device as recited in claim 1, wherein the gate contact extends further in the transverse direction than along the longitudinal axis.

5. The semiconductor device as recited in claim 1, wherein the gate contact has a portion that overhangs the gate.

6. The semiconductor device as recited in claim 5, wherein the portion that overhangs the gate extends over a gate sidewall spacer.

7. The semiconductor device as recited in claim 1, wherein the gate contact includes a plurality of gate contacts on opposite sides of the source/drain contact and the plurality of gate contacts are shifted off-center in opposite directions from the source/drain contact.

8. The semiconductor device as recited in claim 1, wherein the offset is up to 50% of a width of the gate contact.

9. A semiconductor device, comprising:
a P-type source/drain region;
an N-type source/drain region disposed in a parallel direction and spaced apart from the P-type source/drain region;
a source/drain contact contacting the P-type source/drain region and the N-type source/drain region;
first gates spanning over the P-type source/drain region and the N-type source/drain region on a first side of the source/drain contact, the first gates having a centerline in a transverse direction to the parallel direction;
second gates spanning over the P-type source/drain region and the N-type source/drain region on a second side of the source/drain contact opposite the first side, the second gates having a centerline in a transverse direction to the parallel direction;
first gate contacts connecting to the first gates at a position that is offset from the centerline of the first gates away from the source/drain contact; and
second gate contacts connecting to the second gates at a position that is offset from the centerline of the second gates away from the source/drain contact.

10. The semiconductor device as recited in claim 9, wherein the first gate contacts are positioned off-center relative to the P-type source/drain region and the N-type source/drain region.

11. The semiconductor device as recited in claim 9, wherein the second gate contacts are positioned off-center relative to the P-type source/drain region and the N-type source/drain region.

12. The semiconductor device as recited in claim 9, wherein the first gate contacts are longer in the transverse direction.

13. The semiconductor device as recited in claim 9, wherein the second gate contacts are longer in the transverse direction.

14. The semiconductor device as recited in claim 9, wherein at least one gate contact of the first gate contacts and the second gate contacts has a portion that overhangs a gate corresponding to the at least one gate contact.

15. The semiconductor device as recited in claim 14, wherein the portion that overhangs the gate overlaps a gate sidewall spacer.

16. The semiconductor device as recited in claim 9, wherein the first gate contacts and the second gate contacts are shifted off-center in opposite directions from the source/drain contact.

17. The semiconductor device as recited in claim 9, wherein at least one gate contact of the first gate contacts and the second gate contacts includes an offset is up to 50% of a width of the at least one gate contact in the parallel direction.

18. A semiconductor device, comprising:
a source/drain contact contacting parallel source/drain regions;
a gate having a centerline in a transverse direction to the parallel source/drain regions; and
a gate contact connecting to the gate at a position that is offset from the centerline away from the source/drain contact.

19. The semiconductor device as recited in claim 18, wherein the gate contact is longer in the transverse direction.

20. The semiconductor device as recited in claim 18, wherein the gate contact has a portion that overhangs the gate.
